(19) United States
(12) Patent Application Publication
(10) Pub. No.: US 2024/0352574 A1
(43) Pub. Date: Oct. 24, 2024

(54) PROCESSING KIT SHIELD

(71) Applicant: Applied Materials, Inc., Santa Clara, CA (US)

(72) Inventors: Sundarapandian Ramaling Vijayalaskshmi REDDY, Bangalore (IN); Jianxin LEI, Fremont, CA (US); Kirankumar Neelasandra SAVANDAIAH, Bangalore (IN); Zheyuan CHEN, Santa Clara, CA (US); Avinash NAYAK, Bangalore (IN)

(21) Appl. No.: 18/303,318

(22) Filed: Apr. 19, 2023

(51) Int. Cl. C23C 14/34; C23C 14/00; C23C 14/06

(52) U.S. Cl. CPC C23C 14/34; C23C 14/0036; C23C 14/0641; H01J 37/3244; H01J 37/3417; H01J 2237/022; H01J 2237/026; H01J 2237/332

(57) ABSTRACT

A process kit assembly for a process station that includes a cover ring and a shield. The shield includes a lower shield portion configured to interleave with the cover ring. The shield also includes an upper shield portion including a shield port extending from an inner side to an outer side of the upper shield portion. The upper shield portion further includes a shadow surface formed on the inner side configured to shadow the shield port from sputtering deposits. The upper shield portion further includes an upper shield shoulder formed on the outer side. The upper shield portion further includes a lower shield shoulder formed on a lower end of the upper shield portion. The upper shield portion is engageable with an adapter to form an annular chamber around the outer side between the upper shield shoulder and the lower shield shoulder.

### BACKGROUND

### Field

Embodiments of the present disclosure generally relate to substrate processing equipment, and more specifically to process kit shields for use in substrate processing equipment.

### Description of the Related Art

Titanium nitride layers are conventionally deposited during a sputtering process that includes injecting nitrogen gas into the process chamber through a bottom-side nitrogen gas injection system. Nitrogen gas injected by a bottom-side injection system tends to be unevenly distributed along the surface of the substrate, with the upper edge of the substrate surface seeing more nitrogen gas than the upper surface of the substrate closer to the center of the substrate. This uneven distributed is caused by the flow path of the nitrogen gas into the process region of the process chamber containing the substrate and titanium containing target. The bottom-side injection system injects the nitrogen gas behind a shield disposed in the process chamber. The nitrogen flows into the processing region through a flow path between a pedestal and the shield. The nitrogen gas flows around the upper edges of the substrate as the nitrogen enters the process region through the flow path, and the amount of nitrogen gas above the substrate tends to decrease from the edge to the center of the substrate. As a result, the deposited titanium nitride layer has a non-uniform concentration of nitrogen, with the concentration of nitrogen in the layer similarly decreasing from the edge to the center of the deposited layer. A non-uniform nitrogen concentration in the titanium nitride layer causes the threshold voltage in the deposited layer to be non-uniform. Thus, the individual semiconductor devices manufactured on the substrate have different threshold voltages caused by the non-uniformity in the nitrogen concentration.

Therefore, there is a need in the art for a process kit that promotes the uniform distribution of nitrogen gas along the surface of the target to deposit a titanium nitride layer with a more uniform nitrogen percentage across the deposited layer.

### SUMMARY

In one or more embodiments, a process station includes a housing including walls and an adapter that includes at least one first gas inlet port. The process station further includes a pedestal disposed in the housing. The process station further includes a cover ring, a target, a shield, and a chamber. The cover ring includes a cover ring lip assembly with a top surface. The target includes a lower surface disposed in the housing above the pedestal. The shield includes one or more shield ports and a shield lip assembly interleaved with the cover ring lip assembly. The one or more shield ports are located at a position below the lower surface of the target and above the top surface of the cover ring to direct a first gas at the target. The chamber is disposed between the adapter and the shield, and the chamber is in communication with the one or more shield ports and the at least one first gas inlet port.

In one or more embodiments, a process kit assembly for a process station includes a cover ring and a shield. The shield includes a lower shield portion configured to interleave with the cover ring. The shield also includes an upper shield portion including a shield port extending from an inner side to an outer side of the upper shield portion. The upper shield portion further includes a shadow surface formed on the inner side configured to shadow the shield port from sputtering deposits. The upper shield portion further includes an upper shield shoulder formed on the outer side. The upper shield portion further includes a lower shield shoulder formed on a lower end of the upper shield portion. The upper shield portion is engageable with an adapter to form an annular chamber around the outer side between the upper shield shoulder and the lower shield shoulder.

In one or more embodiments, a method of depositing a layer on a substrate includes injecting a first gas into process region of a process station through one or more shield ports formed in a shield disposed within the processing station. The one or more shield ports are positioned to direct the first gas at a processing surface of a target. The method further includes injecting a second gas into the processing station behind the shield. The second gas flows into the processing region through a flow path between a shield lip assembly of the shield that is interleaved with a cover ring.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments of the disclosure and are therefore not to be considered limiting of its scope, as the disclosure may admit to other equally effective embodiments.

FIG. 1 illustrates a schematic cross-sectional view of a process station according to one embodiment.

FIG. 2 illustrates an enhanced cross-sectional view of the process station within the circled region shown in FIG. 1.

FIG. 3 illustrates a graph showing a comparison of the non-uniformity of nitrogen in titanium nitride layers.

FIG. 4 illustrates a flow chart of a sputtering process to deposit a titanium nitride layer on a substrate in accordance with one embodiment.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

An apparatus for reducing the non-uniformity of the nitrogen percentage (e.g., concentration) in a titanium nitride layer is provided herein. The apparatus includes a shield that directs the nitrogen gas to a target such that the nitrogen gas is more uniformly distributed over the target during a sputtering process.

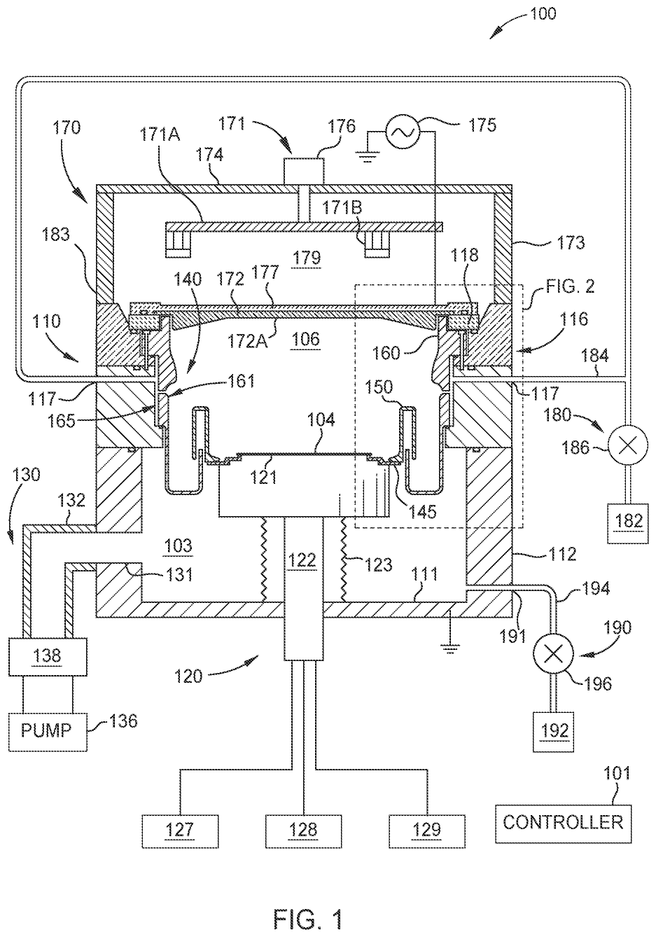

FIG. 1 illustrates a cross-sectional view of a process station 100. The process station 100 may be a station within a substrate processing system, such as a cluster tool comprising a plurality of processing stations configured to process a substrate. As shown in FIG. 1, the process station 100 includes a housing 110, a pedestal 120, an exhaust assembly 130, a process kit assembly 140, a source assembly 170, a first gas assembly 180, and a second gas assembly 190. A controller 101 is in communication with the process station 100 and controls the one or more components of the process station 100.

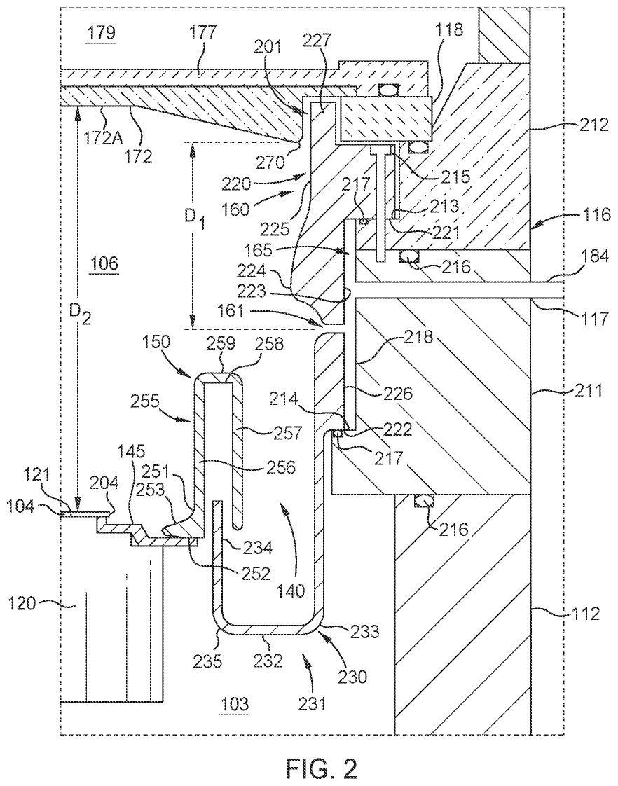

The housing 110 includes one or more chamber walls 112 and an adapter 116. The one or more chamber walls 112 are grounded and the adapter is grounded to the chamber walls 112. The adapter 116 is attached to the upper end of the one or more chamber walls 112 and supports the source assembly 170. The adapter 116 may include inlet ports 117, such as the two inlet ports 117 disposed at opposing sides of the adapter 116. The inlet ports 117 are in communication with an annular chamber 165 disposed between the adapter 116 and a shield 160 of the process kit assembly 140. In some embodiments, the one or more chamber walls 112 and adapter 116 are composed of an aluminum alloy. The adapter 116 is described in further detail with respect to FIG. 2.

The pedestal 120 is at least partially disposed in the interior of the process station 100 to support a substrate 104 during processing. The pedestal 120 may be an electrostatic chuck. The pedestal 120 includes a support surface 121 and a shaft 122. The support surface 121 supports the substrate 104 during processing. A bellows 123 is disposed around the shaft 122 and is engaged with a lower surface 111 of the housing 110 to seal the interior of the process station 100 from the exterior environment (e.g., atmospheric air). A pedestal power source 127 is coupled to the pedestal 120 to provide RF power and/or direct current (DC) power to the pedestal 120 during the processing. For example, the pedestal power source 127 may be configured to bias one or more chucking electrodes (not shown) disposed in the pedestal 120. A back-side gas source 128 may be coupled to the pedestal 120 to inject a back-side gas (e.g., N₂, He, Ar) through the pedestal 120 and into one or more channels (not shown) formed in the support surface 121. These one or more channels allow the back-side gas to flow underneath the back-side of the substrate 104 to regulate the temperature of the substrate 104 during processing. In some embodiments, an additional temperature regulation system 129 is coupled to the pedestal 120. For example, the temperature regulation system 129 may be configured to supply electrical power to one or more heaters disposed in the pedestal 120 to regulate the temperature of the substrate 104. In some embodiments, the temperature regulation system 129 may be a coolant system that circulates a liquid coolant through a flow path formed in the pedestal 120 to regulate the temperature of the substrate 104.

FIG. 1 shows the pedestal 120 in a process position. The pedestal 120 is moveable vertically between a transfer position (e.g., lower position) and the process position (e.g., upper position), including positions therebetween, within the housing 110. In some embodiments, a robot (not shown) may insert the substrate 104 through a slit valve (not shown) in the housing 110 while the pedestal 120 is in the transfer position and a cover ring 150 is lifted from the pedestal 120 by one or more lift pins (not shown) or by being supported by another portion of the process kit assembly 140 as the pedestal 120 is lowered into the transfer position. The substrate 104 is then transferred from the robot to the support surface 121, such as by using additional lift pins (not shown) to facilitate the transfer from the substrate 104 from the robot to the pedestal 120. The cover ring 150 is lowered back into engagement with the pedestal 120 or engages the pedestal 120 as the pedestal 120 is thereafter raised to the process position to facilitate processing the substrate 104.

The exhaust assembly 130 is coupled to the housing 110. The exhaust assembly 130 may include a conduit 132 connecting an exhaust port 131 formed in the housing 110 to a pump 136 configured to evacuate gases from the interior of the processing station 100. A valve 138 may be coupled to the conduit 132. The exhaust assembly 130 is used to evacuate the interior of the process station 100 and to maintaining a desired pressure inside the process station 100, such as maintaining a desired pressure in the process region 106.

The process kit assembly 140 comprises various components that can be easily removed from the interior of the process station 100, for example, to clean sputtering deposits off the component surfaces, replace or repair eroded components, or to adapt the process station 100 for other processes. In one embodiment, the process kit assembly 140 includes a deposition ring 145, the cover ring 150, and the shield 160. The deposition ring 145 is engaged with the pedestal 120, and the cover ring 150 is engaged with the deposition ring 145. For example, the cover ring 150 may rest on the deposition ring 145. The deposition ring 145 and the cover ring 150 move relative to the shield 160 as the pedestal 120 moves within the process station 100. The cover ring 150 interleaves with the shield 160 such that a selectively closeable flow path is present between the cover ring 150 and the shield 160.

The shield 160 is disposed in the housing 110 and coupled to the adapter 116. The shield 160 is grounded by contact with the adapter 116 that is grounded to the chamber walls 112. The shield 160 generally encircles a processing surface 172A of a physical vapor deposition (PVD) target 172 of the source assembly 170. The shield 160 covers and shadows components behind the shield 160 to reduce deposition of sputtering deposits originating from the target 172 onto the components and surfaces behind the shield 160. For example, the shield 160 can protect the chamber walls 112, the adapter 116, and surfaces of the pedestal 120.

In some embodiments, the shield 160 is a single piece. A single piece shield improves the thermal stability of the shield 160 as compared to multi-piece shields. The shield 160 may be formed from any suitable material compatible with a PVD processes, such as titanium (Ti), titanium nitride (TiN), tungsten (W), tungsten nitride (WN), copper (Cu), or aluminum (Al) deposition processes. For example, the shield 160 may comprise stainless steel, aluminum, titanium, aluminum silicon, copper, or combinations thereof.

The shield 160 includes one or more shield ports 161 that are in communication with the annular chamber 165 disposed between the shield 160 and the adapter 116. As will be discussed in more detail with respect to FIG. 2, the one or more shield ports 161 are positioned to promote the deposition of a titanium nitride layer on the substrate 104 that has a more uniform nitrogen percentage (e.g., concentration) throughout the layer.

FIG. 1 illustrates the source assembly 170 adapted to perform a PVD process (e.g., sputtering process). The exemplary source assembly 170 includes a magnetron assembly 171, the target 172, source assembly walls 173 coupled to the housing 110, a lid 174, a sputtering power supply 175, and a backing plate 177. The target 172 comprises a material to be deposited on the substrate 104 during sputtering, such as a metal or metal oxide. For example, the target 172 may be made of a titanium containing material to facilitate the deposition of a titanium nitride layer on the substrate 104. While the target 172 is shown as concave target in FIG. 1, the target 172 can be a flat target or a target having a different configuration. The backing plate 177 is coupled to the target 172 and disposed between the target 172 and the magnetron assembly 171. The backing plate 177 may support the target 172 during sputtering, such as improving the structural stability of the target 172. A dielectric insulator 118 is disposed between the adapter 116 and the backing plate 177. The magnetron assembly 171 includes a magnetron region 179 in which a magnetron 171A is rotated by use of a magnetron rotation motor 176 during processing. The target 172 and magnetron assembly 171 are typically cooled by the delivery of a cooling fluid (e.g., deionized water) to the magnetron region 179 from a fluid recirculation device (not shown). The magnetron assembly 171 includes a plurality of magnets 171B that are configured to generate magnetic fields that extend below the processing surface 172A of the target 172 to promote a sputtering process performed in a process region 106 during a PVD process. The process region 106 is the interior space within the process station 100 where the sputtering process occurs. The process region 106 includes and is at least partially defined by the target 172 and the support surface 121. The process region 106 is also bounded by the shield 160 interleaved with the cover ring 150.

The first gas assembly 180 is configured to inject a first gas into the process region 106 through the inlet ports 117 formed in the adapter 116, the annular chamber 165, and the one or more shield ports 161 formed in the shield 160. The first gas assembly 180 includes a first gas source 182, which may be a gas panel. The first gas may be one or more a process gases, such as one or more precursor gases. For example, the first gas source 182 may supply a nitrogen containing gas, such as nitrogen gas (N₂), to interact with a titanium containing target 172 to form a titanium nitride layer on the substrate 104. In some embodiments, and as shown in FIG. 1, a branched fluid conduit 184 connects the first gas source 182 to the two inlet ports 117 formed on opposing sides of the adapter 116. A first mass flow controller 186 may be coupled to the first conduit 184 to regulate the amount of first gas flowing into the process region 106. The first gas assembly 180 is a top-side gas injection assembly because the first gas is injected into the process station 100 above the top-side of the shield 160 (e.g., the surface of the shield 160 facing the process region 106).

A second gas assembly 190 is configured to inject a second gas into the interior of the process station 100. The second gas assembly 190 includes a second gas source 192. The second gas source 192 may be a gas panel configured to supply the second gas into a lower region 103 of the process station 100 through a second conduit 194 extending from the second gas source 192 to a second inlet port 191 formed in the chamber walls 112 of the housing 110. The second inlet port 191 is located below the shield 160 to inject the second gas into the lower region 103 of the process station 100 that is located between the bottom-side of the shield 160 (e.g., the surface of the shield facing the lower region 103) and the chamber walls 112. As a result, the second gas flows into the process region 106 from the lower region 103 through a flow path between the shield 160 and the cover ring 150. Thus, the second gas assembly 190 is a bottom-side gas injection system since the second gas is injected behind the shield 160 and has to flow through the flow path between the cover ring 150 and shield 160 in order to enter the process region 106. The second gas may be an inert gas, such as Argon. In some embodiments, the second gas is a mixture of one or more gases. The second gas may flow into the process region 106 during processing of the substrate 104, such as while the first gas is injected into the process region 106. In some embodiments, the second gas is used to purge the process region 106 of the first gas. A second mass flow controller 196 may be coupled to the second conduit 194 to regulate the amount of second gases flowing into the lower region 103. In some embodiments, the first gas source 182 and the second gas source 192 may be the same gas source, such as being the same gas panel. In some embodiments, the second inlet port 191 is located at a position below the support surface 121, such as being located at the lower surface 111.

The controller 101 may include a programmable central processing unit (CPU) which is operable with a memory (e.g., non-volatile memory) and support circuits. The support circuits are conventionally coupled to the CPU and comprise cache, clock circuits, input/output subsystems, power supplies, and the like, and combinations thereof coupled to the various components of the station 100, to facilitate control of the station 100. For example, in some embodiments the CPU is one of any form of general-purpose computer processor used in an industrial setting, such as a programmable logic controller (PLC), for controlling various polishing system components and sub-processors. The memory, coupled to the CPU, is non-transitory and is typically one or more of readily available memory such as random access memory (RAM), read only memory (ROM), floppy disk drive, hard disk, or any other form of digital storage, local or remote.

Herein, the memory is in the form of a computer-readable storage media containing instructions (e.g., non-volatile memory), that when executed by the CPU, facilitates the operation of the station 100. The instructions in the memory are in the form of a program product such as a program that implements the methods of the present disclosure (e.g., middleware application, equipment software application, etc.). The program code may conform to any one of a number of different programming languages. In one example, the disclosure may be implemented as a program product stored on computer-readable storage media for use with a computer system. The program(s) of the program product define functions of the embodiments (including the methods and operations described herein).

Illustrative computer-readable storage media include, but are not limited to: (i) non-writable storage media (e.g., read-only memory devices within a computer such as CD-ROM disks readable by a CD-ROM drive, flash memory, ROM chips or any type of solid-state non-volatile semiconductor memory) on which information is permanently stored; and (ii) writable storage media (e.g., floppy disks within a diskette drive or hard-disk drive or any type of solid-state random-access semiconductor memory) on which alterable information is stored. Such computer-readable storage media, when carrying computer-readable instructions that direct the functions of the methods described herein, are embodiments of the present disclosure.

FIG. 2 is an enhanced view of the circled region in FIG. 1 to better show the adapter 116, process kit assembly 140, and the annular chamber 165. As shown in FIG. 2, the adapter 116 includes a lower adapter portion 211 and an upper adapter portion 212. The lower adapter portion 211 is engaged with the upper end of the chamber walls 112. A seal 216 is disposed between the interface of the lower adapter portion 211 and the chamber walls 112 to prevent communication between the lower region 103 and the outside environment. Another seal 216 is disposed between the interface of the upper adapter portion 212 and the lower adapter portion 211.

The upper adapter portion 212 includes an upper adapter shoulder 213 and the lower adapter portion 211 includes a lower adapter shoulder 214. An inner surface 218 of the adapter 116 extends from the upper adapter shoulder 213 to the lower adapter shoulder 214. The inlet port 117 is formed in the lower adapter portion 211 and terminates at an opening formed in the inner surface 218. The lower adapter portion 211 may be attached to the upper adapter portion 212 by fasteners (not shown), such as bolts. The fasteners may be inserted into openings formed in the upper adapter shoulder 213.

The shield 160 is shown as being a single piece metal body that includes an upper shield portion 220 and a lower shield portion 230. In some embodiments, the shield 160 may be made of multiple pieces. The upper shield portion 220 may be a generally cylindrical body with an inner side 225 and an outer side 226. The upper shield portion 220 includes an upper shield shoulder 221 formed on the outer side 226 that protrudes from the cylindrical body. The upper shield portion 220 also includes a lower shield shoulder 222 at the bottom end (e.g., lower end) of the upper shield portion 220. As shown, the lower shield shoulder 222 is located adjacent to where the upper shield portion 220 and lower shield portion 230 connect. The upper shield shoulder 221 and lower shield shoulder 222 are separated by an outer surface 223 that faces the inner surface 218 of the adapter 116. The upper shield shoulder 221 is engaged with the upper adapter shoulder 213, and the lower shield shoulder 222 is engaged with the lower adapter shoulder 214. The annular chamber 165 (e.g., annular plenum) is disposed between the upper shield portion 220 and the adapter 116 between the opposing surfaces 218, 223. The annular chamber 165 is also disposed between the adjoining upper shoulders 213, 221 and lower shoulders 214, 222. The annular chamber 165 may extend completely around the circumference of upper shield portion 220. A seal 217, such as an O-ring, is disposed between the interface of the adjoining upper shoulders 213, 221 and the adjoining lower shoulders 214, 222 to prevent leakage of the first gas therebetween. Thus, the seals 217 maintain the pressure integrity of the annular chamber 165 so that the nitrogen pressure is uniform within the annular chamber 165. Maintaining a uniform pressure within the annular chamber 165 allows for the gas to exit the one or more shield ports 161 at a constant flow rate to promote the uniform distribution of the nitrogen gas across the processing surface 172A of the target 172.

Fasteners 215, such as a bolts, are used to secure the shield 160 to the adapter 116 and to ensure that the seals 217 are maintained in a tight sealing engagement with the adapter 116 and the shield 160. The fasteners 215 may extend through the upper shield shoulder 221 and into the lower adapter portion 211 and upper adapter portion 212.

An upper end 227 of the upper shield portion 220 is disposed between a protruding edge region 270 of the concave target 172 and the dielectric insulator 118. A dark space gap 201 is present between the electrically biased target 172 and the upper end 227. The dark space gap 201 further extends between the upper end 227 and the dielectric insulator 118. The dark space gap 201 is sized to limit and/or prevent the sustained presence of plasma as well as to prevent shorting (grounding) or arching of the biased target 172 to the grounded shield 160. Thus, the upper end 227 is sized and shaped to form the dark space gap 201 when the shield 160 is placed in the process station 100 for a processing operation.

The one or more shield ports 161 are formed through the upper shield portion 220 and extend from the inner side 225 to the outer side 226. The one or more shield ports 161 are arranged around the process region 106, such as being equally spaced around the shield 160. Without being bound by theory, it is believed that directing the nitrogen gas at the target 172, as opposed to directing the nitrogen gas toward the substrate, results in a more complete reaction that improves the uniformity of the nitrogen concentration in the deposited titanium nitride layer. Improving the uniformity of the nitrogen concentration within the deposited titanium nitride layer also improves the uniformity of the threshold voltage across the layer.

As shown in FIG. 2, the center of the shield ports 161 are disposed at a distance D1 below the processing surface 172A of the target. This distance D1 is shown as being the vertical distance between the center of the shield port 161 and the closest part of the target 172, such as the bottom of the protruding edge regions 270. The shield ports 161 are spaced from the processing surface 172A by distance D1 to promote the uniform distribution of the first gas (e.g., nitrogen gas) across the entire processing surface 172A during a sputtering (e.g., PVD) process. In other words, the shield ports 161 are located at a distance relative to the target 172 to direct the injected nitrogen gas at the target 172 while promoting the even distribution of the nitrogen gas over the processing surface 172A. Directing that gas at target 172 promotes the reaction of the nitrogen gas with the target 172 while reducing the reaction of the nitrogen gas with the material being deposited on the surface of the substrate 104. As a result, the percentage of nitrogen in the deposited titanium nitride layer is more uniform from the center to the edge of the titanium nitride layer than in a titanium nitride layer deposited using a bottom-side nitrogen injection process.

Positioning the one or more shield ports 161 too close or too far away from the target 172 will reduce the uniformity of the nitrogen concentration within the titanium nitride layer. If the one or more shield ports 161 are located too close to the target 172, then the nitrogen gas will be less evenly distributed over the processing surface 172A with more nitrogen gas being concentrated at the edges of the processing surface 172A as comparted to the center of the processing surface 172A. This uneven distribution of the nitrogen will result in a titanium nitride layer with a less even nitrogen concentration. If the one or more shield ports 161 are located too far away from the target 172, such as being in line with or positioned vertically below a top surface (see upper surface 259) of the cover ring 150, then the cover ring 150 may deflect the flow of nitrogen gas into the process region 106 leading to an uneven concentration of nitrogen in the titanium nitride layer. Additionally, the nitrogen gas may primarily react with the growing titanium nitride layer on the substrate rather than the target 172 if the shield ports 161 are located too far away from the target 172.

Thus, the shield ports 161 are located at the distance D1 from the target 172A an optimal position to promote the distribution of nitrogen while also avoiding or minimizing flow interference associated with the cover ring 150. In some embodiments, D1 is between 1 inch and 4 inches, such being about 4 inches, such being about 3.5 inches, such as being about 3 inches, such as being about 2.5 inches, such as being about 2 inches, such as being about 1.5 inches, such as being about 1.0 inch. In some embodiments, D1 is about 2.5 inches (about 63.5 mm), such as being within about 1% of 2.5 inches, such as being within about 0.2% of 2.5 inches. In some embodiments, D1 is based on the diameter of the target 172. For example, the ratio of the diameter of the substrate to the position of the shield ports 161 may be a ratio of about 6.8.

In some embodiments, the one or more shield ports 161 are eight or more shield ports. The shield ports 161 may have a diameter of about 0.8 inches (about 20.32 mm). In some embodiments, the one or more shield ports 161 may be more or less than eight shield ports.

The upper shield portion 220 also includes a shadow surface 224 formed on the inner side 225 adjacent to the one or more shield ports 161. The shadow surface 224 shadows the one or more shield ports 161 from the sputtering of material from the target 172 to limit and/or prevent the buildup of sputtered material in the one or more shield ports 161. In other words, the shadow surface 224 helps prevent the buildup of material in the shield ports 161 that could choke the flow of first gas through the shield ports 161 during processing. The shadow surface 224 may be a contoured surface of a protrusion formed on the inner side 225 that extends from the cylindrical body at a location above the shield port 161 that terminates at the entrance of the shield port 161. The shadow surface 224 may be a continuous feature that extends around the inner side 225 of the upper shield portion 220 around the process region 106. For example, the shadow surface 224 may be a contoured circumferential protrusion that extends around the inner side 225 of the upper shield portion 220. In some embodiments, the upper shield portion 220 includes a plurality of discontinuous shadow surfaces 224 that correspond to each shield port 161.

The lower shield portion 230 includes a shield lip assembly 231 which interfaces with the cover ring 150. For example, the shield lip assembly 231 may include a lower surface 232 extending inward from an outer edge 233 of the lower shield portion 230. The shield lip assembly 231 includes a lip 234 disposed about an inner edge 235 of the lower surface 232 and extending upward from the inner edge 235 towards the upper shield portion 220.

The deposition ring 145 and the cover ring 150 cooperate with one another to reduce formation of sputter deposits on the peripheral edges of the substrate support surface 121 and an overhanging edge 204 of the substrate 104. The cover ring 150 interleaves with the shield lip assembly 231 such that a selectively closeable flow path is present between the cover ring 150 and the shield 160.

The deposition ring 145 is engaged with the pedestal 120 and is generally formed in an annular shape, or annular band, surrounding the support surface 121. The deposition ring 145 may be formed from a dielectric material that is resistant to a sputtering process, such as being made of a ceramic material, such as aluminum oxide.

The cover ring 150 shown in FIG. 2 is a tall cover ring. The cover ring 150 includes an annular body 251 having a footing 252. The cover ring 150 is supported on the deposition ring 145 by the engagement of the footing 252 with the deposition ring 145. The cover ring 150 encircles and at least partially covers the deposition ring 145 to shadow the deposition ring 145 from the bulk of the sputtering deposits. The cover ring 150 is fabricated from a material that can resist erosion by the sputtering plasma, for example, a metallic material such as stainless steel, titanium or aluminum, or a ceramic material, such as aluminum oxide. The annular body 251 also includes a projecting brim 253 that is positioned to reduce deposition of sputtering deposits on the upper surface of the deposition ring 145.

The cover ring 150 also includes a cover ring lip assembly 255 extending upward from the annular body 251. The cover ring lip assembly 255 includes an inner ring 256 and an outer ring 257 separated from one another by an upper portion 258. The inner ring 256 and outer ring 257 extend downwardly from the upper portion 258 and are located radially outward of the footing 252 of the brim 253. A gap is disposed between the rings 256, 257 sized to interleave with the shield lip assembly 231. As shown, the lip 234 of the shield 160 extends upwards between the adjacent downward extending inner and outer cylindrical rings 256, 257 of the cover ring 150. The cover ring lip assembly 255 has a height that shadows the substrate 104 from the nitrogen gas being injected into the process region 106 from the shield ports 161. In other words, the cover ring lip assembly 255 has a height that obstructs a direct line of sight between the shield ports 161 and the surface of the substrate 104 to limit the amount of nitrogen that reaches the surface of the substrate 104. As shown in FIG. 2, the cover ring lip assembly 255 extends above the substrate support surface 121. Further, the upper portion 258 is shown as disposed at a position between the upper and lower shoulders 221, 222 of the shield 160 while also being positioned below the shield ports 161 such that the upper surface 259 of the upper portion 258 is below the shield ports 161. The height of the cover ring lip assembly 255 may be selected based on the desired shadowing effect.

Additionally, the cover ring lip assembly 255 has a height that accommodates the vertical movement of the pedestal 120. As shown in FIG. 2, the pedestal 120 is at a position such that the shield lip assembly 231 is not in contact with the cover ring lip assembly 255. Thus, a flow path is present between the interleaved shield lip assembly 231 and cover ring lip assembly 255 that allow the second gas to flow into the process region 106 from the lower region 103. The flow path may be present when the pedestal 120 is in the process position. As shown in FIG. 2, the flow path is convoluted S-shaped pathway defined by the interleaved shield lip assembly 231 and cover ring lip assembly 255. The pedestal 120 may be moved to one or more positions to change the length of the flow path, such as by raising or lowering the cover ring lip assembly 255 relative to the shield lip assembly 231. In some embodiments, the outer ring 257 and the lip 234 are sized such that the pedestal 120 can be lowered to place the lip 234 into contact with the upper portion 258 to seal the process region 106 from the lower region 103.

FIG. 2 also shows a distance D2 between the upper surface of the substrate 104 and the flat part of the processing surface 172A of the target 172 during processing. In some embodiments, the distance D2 is between about 150 mm to 190 mm, such as between about 160 mm and 180 mm. The pedestal 120 may be moved vertically during processing to selectively change the distance D2 between processing surface 172A of the target 172 and the surface of the substrate 104 during processing

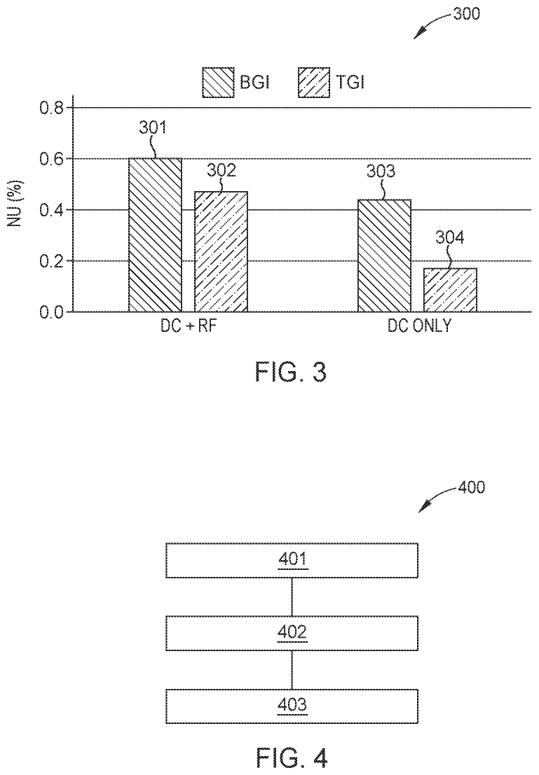

FIG. 3 illustrates a graph 300 comparing the non-uniformity of the percentage of nitrogen in different titanium nitride layers that are 35 Angstroms thick. The Y-axis shows the percentage of non-uniformity, expressed as NU (%), of the nitrogen in the titanium nitride layer as measured across the substrate 104. The first set of bar graphs (e.g., bar 301 and bar 302) on the left side of the graph 300 is comparing the non-uniformity of nitrogen in a titanium nitride layer formed in a sputtering process using both RF and direct current power. Bar 301 represents the non-uniformity of the nitrogen in a titanium nitride layer formed by a conventional bottom-side gas injection (BGI). Bar 302 represents the non-uniformity of the nitrogen in a titanium nitride layer formed using the top-side gas injection (TGI) process disclosed herein. As shown, the titanium nitride layer formed using the conventional bottom-side gas injection technique has a more non-uniform percentage of nitrogen than the titanium nitride layer formed using top-side gas injection.

The second set of bar graphs (e.g., bar 303 and bar 304) on the right side of the graph 300 is comparing the non-uniformity of nitrogen in titanium nitride layers formed by a sputtering process using only direct current power. Bar 303 represents the non-uniformity of the nitrogen in a titanium nitride layer formed by a conventional bottom-side gas injection. Bar 304 represents the non-uniformity of the nitrogen in a titanium nitride layer formed using the top-side gas injection process disclosed herein. As shown, the titanium nitride layer formed using the conventional bottom-side gas injection technique has a more non-uniform percentage of nitrogen than the titanium nitride layer formed using top-side gas injection.

In some embodiments, a titanium nitride layer formed using the processes disclosed herein have a nitrogen non-uniformity between about 0.5% and about 0%. For example, the nitrogen non-uniformity may be less than about 0.45%, such as being less than 0.4%, such as being less than about 0.35%, such as being less than 0.3%, such as being less than 0.25%, such as being less than 0.2%, such as being less than about 0.5%.

FIG. 4 is a flow chart of a sputtering process 400 to deposit a titanium nitride layer on a substrate within process station 100. As shown by activity 401, power is applied to the titanium sputtering target 172 by the sputtering power supply 175 while the substrate 104 is chucked to support surface 121 of the pedestal 120. As shown by activity 402, nitrogen is injected into the process region 106 from the first gas assembly 180. The nitrogen enters the process region 106 on the top-side of the shield 160 through the shield ports 161 which are positioned to direct the nitrogen gas at the processing surface 172A of the titanium containing target 172. As shown by activity 403, a second gas, such as Argon, is injected into the lower region 103 of the process station 100 from the second gas assembly 190. The second gas flows into the process region 106 through the flow path between the interleaved shield lip assembly 231 and cover ring lip assembly 155. The length of the flow path may be selectively changed during processing. In some embodiments, the pedestal 120 may be moved to selectively open and close the flow path during processing. The thickness of the deposited titanium nitride layer may be adjusted by changing the processing time of the sputtering process 400.

In some embodiments, the processes disclosed herein may be used to achieve a desirable concentration of a material in a layer formed on a substrate that is formed by sputtering. For example, the processes disclosed herein may be used to deposit a tantalum nitride (TaN), tungsten nitride (WN), silicon nitride (SiN), or aluminum nitride (AlN) layer with improved uniformity of the nitrogen concentration.

While the foregoing is directed to embodiments of the present disclosure, other and further embodiments of the disclosure may be devised without departing from the basic scope thereof, and the scope thereof is determined by the claims that follow.

What is claimed is:

1. A process station, comprising:
a housing including walls and an adapter that includes at least one first gas inlet port;
a pedestal disposed in the housing;
a cover ring including a cover ring lip assembly with a top surface;
a target including a lower surface disposed in the housing above the pedestal;
a shield including one or more shield ports and a shield lip assembly interleaved with the cover ring lip assembly, wherein the one or more shield ports are located at a position below the lower surface of the target and above the top surface of the cover ring to direct a first gas at the target; and
a chamber disposed between the adapter and the shield, wherein the chamber is in communication with the one or more shield ports and the at least one first gas inlet port.

2. The process station of claim 1, wherein the shield includes at least one shadow surface configured to shadow the one or more shield ports from the sputtering of material from the target.

3. The process station of claim 2, wherein the at least one shadow surface is one shadow surface that extends around an inner side of the shield.

4. The process station of claim 2, wherein the at least one shadow surface is a plurality of discontinuous shadow surfaces corresponding to a respective shield port of the at least one shield ports.

5. The process station of claim 1, wherein the adapter includes an upper adapter portion and a lower adapter portion, the least one first gas inlet port being formed through the lower adapter portion.

6. The process station of claim 1, wherein:
the shield includes an upper shield shoulder and a lower shield shoulder; and
the adapter includes an upper adapter shoulder engaged with the upper shield shoulder and a lower adapter shoulder engaged with the lower shield shoulder, wherein the chamber is disposed between the lower shield shoulder and the upper shield shoulder.

7. The process station of claim 1, wherein the one or more shield ports are disposed between an upper shield shoulder and a lower shield shoulder.

8. The process station of claim 1, further comprising:
a second gas inlet port formed in the housing at a location behind the shield, wherein a second gas assembly is configured to inject a second gas behind the shield through the second gas inlet port.

9. The process station of claim 8, wherein the second gas is Argon.

10. The process station of claim 1, wherein the target is a concave target and the lower surface is a surface of a protruding edge region of the concave target.

11. A process kit assembly for a process station, comprising:
a cover ring;
a shield, including:
a lower shield portion configured to interleave with the cover ring; and
an upper shield portion, including:
a shield port extending from an inner side to an outer side of the upper shield portion;
a shadow surface formed on the inner side configured to shadow the shield port from sputtering deposits;
an upper shield shoulder formed on the outer side;
a lower shield shoulder formed on a lower end of the upper shield portion; and
wherein the upper shield portion is engageable with an adapter to form an annular chamber around the outer side between the upper shield shoulder and the lower shield shoulder.

12. The process kit assembly of claim 11, wherein the upper shield portion includes an upper end configured to form a dark space gap between the upper end and a target.

13. The process kit assembly of claim 11, wherein the shield port is positioned between a bottom-most surface of a target and a top surface of the cover ring when the shield and cover ring are disposed within the processing station.

14. The process kit assembly of claim 11, wherein the shadow surface extends around the inner side above the port.

15. The process kit assembly of claim 11, wherein the cover ring includes a cover ring lip assembly that is configured to interleave with a shield lip assembly of the lower shield portion, wherein a flow path is disposed between the cover ring lip assembly and the shield lip assembly.

16. The process kit assembly of claim 11, wherein the shield port is disposed between the upper shield shoulder and the lower shield shoulder.

17. A method of depositing a layer on a substrate, comprising:
injecting a first gas into process region of a process station through one or more shield ports formed in a shield disposed within the processing station, wherein the one or more shield ports are positioned to direct the first gas at a processing surface of a target; and
injecting a second gas into the processing station behind the shield, wherein the second gas flows into the processing region through a flow path between a shield lip assembly of the shield that is interleaved with a cover ring.

18. The method of claim 17, wherein the non-uniformity of first gas in the layer is less than 0.5%.

19. The method of claim 17, wherein the layer is a titanium nitride layer, the first as is nitrogen gas, and the target is a titanium containing target.

20. The method of claim 19, wherein the non-uniformity of a nitrogen non-uniformity in the titanium nitride layer is less than 0.5%.
